(19) United States
(12) Patent Application Publication
(10) Pub. No.: US 2015/0055410 A1
(43) Pub. Date: Feb. 26, 2015

(54) MEMORY CIRCUIT AND METHOD FOR DISSIPATING EXTERNAL MAGNETIC FIELD

(71) Applicant: Krishnakumar Mani, Santa Clara, CA (US)

(72) Inventor: Krishnakumar Mani, Santa Clara, CA (US)

(73) Assignee: MAGSIL CORPORATION, Santa Clara, CA (US)

(21) Appl. No.: 13/153,471

(22) Filed: Jun. 6, 2011

(51) Int. Cl. G11C 11/14

(52) U.S. Cl. 365/171

(57) ABSTRACT

Memory circuit and method for at least partially dissipating an external magnetic field before the magnetic field affects operation of an array of addressable magnetic storage element stacks in the memory circuit. Multiple dummy magnetic storage element stacks are provided around the periphery of the array. Each of the dummy stacks is substantially circular for orienting along the external magnetic field, thereby causing the dissipation. Each of the addressable and the dummy stacks may be formed with a magnetic tunnel junction (MTJ).

### FIELD

Embodiments of the invention relate to a memory circuit using magnetic storage elements and particularly relate to magnetic random access memory (MRAM) circuits.

### BACKGROUND

Magnetic memory circuits are based on magneto-resistive behavior of magnetic storage elements that are integrated typically with a complementary metal-oxide semiconductor (CMOS) technology. Such memory circuits generally provide non-volatility and an unlimited read and write capability. An example is the magnetic random access memory (MRAM) circuit that includes a plurality of bits, each defining an addressable magnetic storage element stack that may include a magnetic tunnel junction (MTJ).

Each MTJ addressable magnetic element stack includes a free layer having a magnetic spin orientation that can be flipped between two states by the application of a magnetic field induced by energizing write conductors.

### SUMMARY OF THE INVENTION

According to an aspect of the invention, a memory circuit comprises an array of addressable magnetic storage element stacks and a plurality of dummy magnetic storage element stacks around the periphery of the array. Each of the dummy stacks is substantially circular for orienting along any external magnetic field, thereby at least partially dissipating the magnetic field before the magnetic field affects the addressable stacks, when in operation.

According to an embodiment, each of the addressable stacks comprises a magnetic tunnel junction (MTJ).

According to another embodiment, each of the dummy stacks comprises a magnetic tunnel junction (MTJ).

According to yet another embodiment, each of the addressable stacks has an area of about 150 nm×180 nm.

According to yet another embodiment, each of the dummy stacks is of about 1 to 2 um in diameter.

According to yet another embodiment, a layout of the plurality of dummy stacks is designed for enhancing a following step of planarization by chemical mechanical polishing.

According to yet another embodiment, the dummy stacks have a plurality of diameter values.

According to another aspect of the invention, a method is proposed for at least partially dissipating an external magnetic field before the magnetic field affects operation of an array of addressable magnetic storage element stacks in a memory circuit. The method comprises a step of engaging a plurality of dummy magnetic storage element stacks around the periphery of the array. Each of the dummy stacks is substantially circular for orienting along the external magnetic field, thereby causing the dissipation.

According to an embodiment of the method, at least one stack of the addressable stacks and the dummy stacks comprises a magnetic tunnel junction (MTJ).

According to the embodiments of the invention, the dummy stacks would prevent the addressable stacks from being undesirably affected by the external magnetic field. A strong external magnetic field may otherwise cause a flip in the corresponding state of the addressable stacks, from ‘0’ to ‘1’ or from ‘1’ to ‘0’.

### BRIEF DESCRIPTION OF THE DRAWINGS

FIG. 1 illustrates a mask layout for creating (a) an array of addressable magnetic storage element stacks on a wafer and (b) dummy magnetic storage element stacks around the periphery of the array of addressable stacks, in accordance with one embodiment of the invention.

FIG. 2A illustrates a plan view of a wafer on which an array of addressable and the dummy stacks have been fabricated using the mask of FIG. 1, wherein the dummy stacks are oriented in a first direction.

FIG. 2B illustrates the plan view at FIG. 2A, with the dummy stacks oriented along a second direction, which is different from the first direction.

FIG. 2C illustrates a perspective view of an addressable stack and a dummy stack, in accordance with one embodiment of the invention.

### DETAILED DESCRIPTION

In the following description, for purposes of explanation, numerous specific details are set forth in order to provide a thorough understanding of the invention. It will be apparent, however, to one skilled in the art that the invention can be practiced without these specific details.

Reference in this specification to “one embodiment” or “an embodiment” means that a particular feature, structure, or characteristic described in connection with the embodiment is included in at least one embodiment of the invention. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

Broadly, embodiments of the invention disclose a method to shield magnetic storage bits/cells of a magnetic circuit from spurious or stray magnetic fields. A magnetic circuit comprising magnetic bits/cells, and a magnetic shielding arrangement to shield the magnetic bits from stray magnetic fields is also disclosed. Advantageously, embodiments of the invention prevent, or at least reduce, data corruption in a magnetic circuit, due to stray magnetic fields.

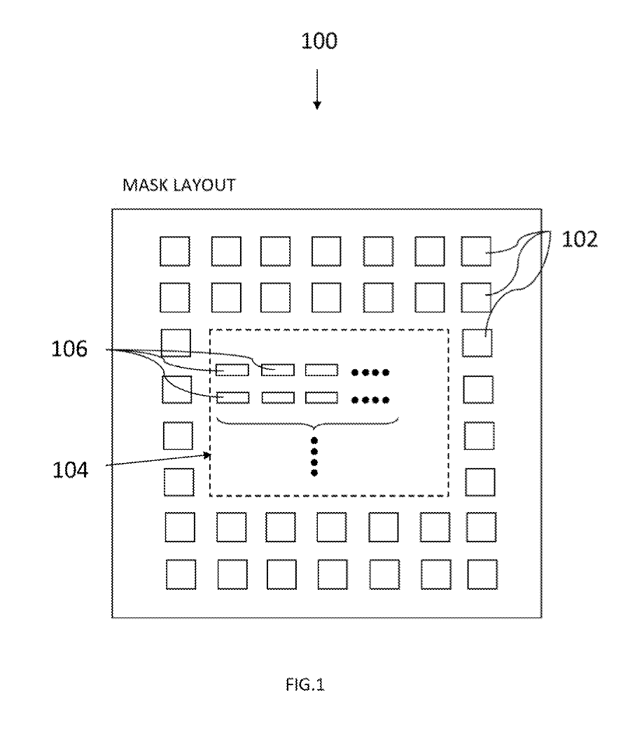

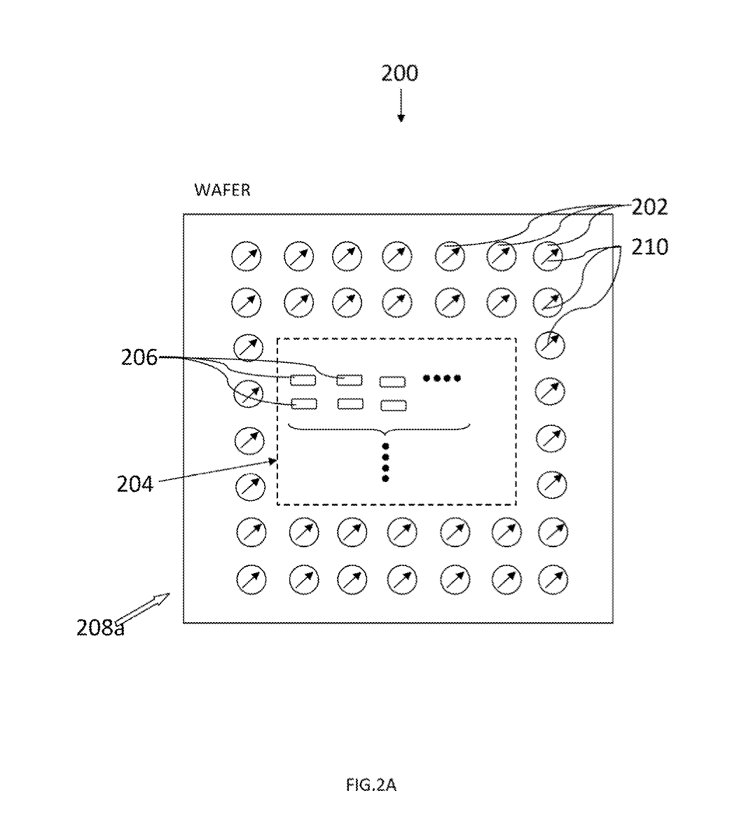

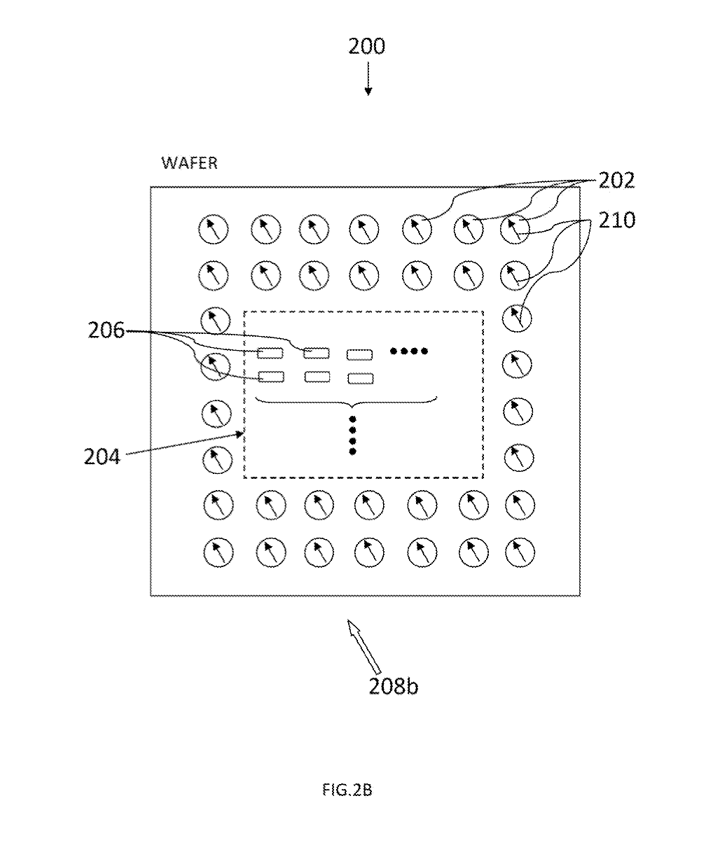

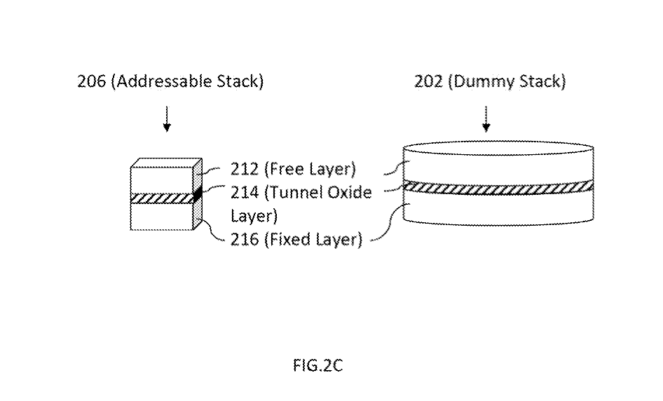

Referring now to FIG. 1 of the drawings, there is shown a mask layout 100, in accordance with one embodiment of the invention. The layout 100 includes mask features 102, and 106. Upon processing, each of the mask features 102 translate to a corresponding dummy magnetic storage element stack 202 (see FIG. 2A of the drawings) on a wafer. Likewise, each of the mask features 106 translate to a corresponding addressable magnetic storage element stack 206 (see FIG. 2A of the drawings) on the wafer. The mask features 106 are arranged in an array 104. The dummy stacks 202 are peripherally disposed with respect to the addressable stacks 206. In FIG. 2A only a few of the dummy stacks 202 have been shown.

In this embodiment, each of the addressable stacks 206 is rectangular. According to other embodiments, using a combination of suitably shaped features 106 in the mask 100 and processing other shapes for the addressable stacks 206 may be realized. Circular shapes for the addressable stacks 206 may however be excluded, as that would undesirably affect the operation, by making the addressable stacks 206 more responsive to the external magnetic field. According one embodiment of the invention, the features 102 are intended to create circular dummy stacks 202 on the wafer 200. According to other embodiments, shapes for the features 102 may be other than square, such as hexagons, provided the corresponding processing technology is capable of creating corresponding circular dummy stacks 202 on the wafer 200.

While processing the wafer 200, a rectangular shape of the addressable stacks 206 is likely to undergo unintentional rounding effects at the corners. However, the circular shape of the dummy stacks 202 is achieved intentionally, even if that needs some extra processing steps. The circular shape enables the dummy stacks 202 to orient along any external magnetic field in any direction as represented by the block arrow 208a, thereby assisting in at least partially dissipating the magnetic field before the magnetic field affects the operation of the addressable stacks 206.

FIG. 2B illustrates the same plan view as at FIG. 2A, but with the dummy stacks 202 being oriented along an external magnetic field that is in a direction as shown by the block arrow 208b. The direction as shown by the block arrow 208b is different from the direction as shown by the block arrow 208a in FIG. 2A.

FIG. 2C illustrates an embodiment, where the addressable stack 206 as a solid rectangular cuboid and the dummy stack 202 as a solid cylinder are both conventional stacks of magnetic tunnel junction (MTJ). A free layer 212, a tunnel oxide layer 214 and a fixed layer 216 for the either MTJ stack are shown. The invention is equally applicable when any other type of magnetic storage element stack is used. Having the same type of stack for both the addressable stack 206 and the dummy stack 202 is favorable in terms of processing complexity and cost. However, according to the embodiments of the invention, the two magnetic stacks 206, 202 may as well be non-identical.

According to an embodiment of the invention, each of said addressable stacks 206 has an area of about 150 nm×180 nm. However, this value is non-exclusive. According to other embodiments, other values and ratios based on the required performance and technology, may equally be used. The term ‘about’ includes a typical processing variation under the fabrication process, as within ±10%.

According to another embodiment of the invention, each of said dummy stacks 202 is of about 1 to 2 um in diameter. This value is again non-exclusive and according to other embodiments, other values may equally be used. Again, the term ‘about’ includes a typical processing variation under the fabrication process, as within ±10%.

According to yet another embodiment of the invention, the dummy stacks 202 may have more than one diameter values. For example, the diameter values may be optimized to achieve an efficient utilization of the space around the periphery of the array 204. Higher the number of the dummy stacks 202 and larger the diameter values, better is the dissipation in the magnetic field.

According to another embodiment of the invention, a layout of said plurality of dummy stacks 202 is designed for enhancing a following step of planarization by chemical mechanical polishing. The dummy stacks 202 are likely to provide additional mechanical support for planarization.

The embodiments of the invention are compatible with any semiconductor technology such as complementary metal-oxide-semiconductor (CMOS), bipolar-junction-transistor and CMOS (BiCMOS), silicon-on-insulator (SOI) and the like. The scope of the invention is also not limited to any particular technology in terms of processing sequence, materials, physical dimensions and the like.

The embodiments of the present invention may be applied to memory circuits for applications in any area, such as in automotive, mobile phone, smart card, radiation hardened military applications, database storage, Radio Frequency Identification Device (RFID), MRAM elements in field-programmable gate array (FPGA) and the like.

Although the present invention has been described with reference to specific exemplary embodiments, it will be evident that the various modification and changes can be made to these embodiments without departing from the broader spirit of the invention. Accordingly, the specification and drawings are to be regarded in an illustrative sense rather than in a restrictive sense.

1. A memory circuit comprising:
an array of addressable magnetic storage element stacks, wherein each addressable magnetic storage element stack has a rectangular cuboid shape; and
a magnetic shielding arrangement configured to shield the addressable magnetic storage element stacks from an external magnetic field;
wherein the magnetic shielding arrangement includes a plurality of dummy magnetic storage element stacks around a periphery of the array; and
wherein each dummy magnetic storage element stack has a cylindrical shape with a circular cross section that orients the respective dummy magnetic storage element with the external magnetic field and causes the respective dummy magnetic storage element to at least partially dissipate the external magnetic field before the external magnetic field affects one or more addressable magnetic storage element stacks of the array.

2. The memory circuit of claim 1, wherein each addressable magnetic storage element stack comprises a magnetic tunnel junction (MTJ).

3. The memory circuit of claim 2, wherein each dummy magnetic storage element stack comprises a magnetic tunnel junction (MTJ).

4. The memory circuit of claim 1, wherein each addressable magnetic storage element stack has an area of about 150 nm×180 nm.

5. The memory circuit of claim 1, wherein each dummy magnetic storage element stack is of about 1 to 2 μm in diameter.

6. The memory circuit of claim 1, wherein a layout of the plurality of dummy magnetic storage element stacks enhances planarization by chemical mechanical polishing.

7. The memory circuit of claim 1, wherein the plurality of dummy magnetic storage element stacks comprise dummy magnetic storage element stacks having a range of different diameter values.

8. A memory circuit comprising:
an array of addressable magnetic storage element stacks, wherein each addressable magnetic storage element stack has a rectangular cross section; and
a magnetic shielding arrangement configured to shield the addressable magnetic storage element stacks from an external magnetic field;
wherein the magnetic shielding arrangement includes a plurality of dummy magnetic storage element stacks around a periphery of the array; and
wherein each dummy magnetic storage element stack has a circular cross section and at least partially dissipates the external magnetic field before the external magnetic field affects one or more addressable magnetic storage element stacks of the array.

9. The memory circuit of claim 8, wherein each dummy magnetic storage element stack comprises a magnetic tunnel junction (MTJ).

10. The memory circuit of claim 8, wherein each addressable magnetic storage element stack has an area of about 150 nm×180 nm.

11. The memory circuit of claim 8, wherein each dummy magnetic storage element stack is of about 1 to 2 μm in diameter.

12. The memory circuit of claim 8, wherein a layout of the plurality of dummy magnetic storage element stacks enhances planarization by chemical mechanical polishing.

13. The memory circuit of claim 8, wherein the plurality of dummy magnetic storage element stacks comprise dummy magnetic storage element stacks having a range of different diameter values.

14. A memory circuit comprising:
a plurality of magnetic storage element stacks, wherein each magnetic storage element stack has a rectangular cross section; and
a plurality of dummy stacks around the periphery of the plurality of magnetic storage element stacks;
wherein each dummy stack has a circular cross section;
wherein the plurality of dummy stacks at least partially dissipates an external magnetic field before the external magnetic field affects one or more magnetic storage element stacks from the plurality of magnetic storage element stacks; and
wherein each magnetic storage element stack and each dummy stack comprises a magnetic tunnel junction (MTJ).

15. The memory circuit of claim 14, wherein each memory storage element stack has an area of about 150 nm×180 nm.

16. The memory circuit of claim 14, wherein each dummy stack is of about 1 to 2 μm in diameter.

17. The memory circuit of claim 14, wherein a layout the plurality of dummy stacks enhances planarization by chemical mechanical polishing.

18. The memory circuit of claim 14, wherein the plurality of dummy stacks comprise dummy stacks having a range of different diameter values.

19. A method of protecting an array of addressable magnetic storage element stacks in a memory circuit from an external magnetic field, the method comprising:
forming the array of addressable magnetic storage element stacks such that each addressable magnetic storage element stack has a rectangular cross section; and
forming a plurality of dummy stacks around a periphery of the array such that each dummy stack has a circular cross section.

20. The method of claim 19, further comprising forming each dummy stack with a magnetic tunnel junction (MTJ).
